(19) United States
(12) Patent Application Publication
(10) Pub. No.: US 2002/0085338 A1
(43) Pub. Date: Jul. 4, 2002

(54) Portable computer with a detachable keyboard device

(75) Inventor: Tai-Hung Lin, Tao-Yuan Hsien (TW)

Correspondence Address: BRINKS HOFER GILSON & LIONE, P.O. BOX 10395, CHICAGO, IL, 60610, US

(73) Assignee: Cirkitech Electronic Co. Ltd.

(21) Appl. No.: 09/833,300

(22) Filed: Apr. 11, 2001

(30) Foreign Application Priority Data
Jan. 2, 2001 (TW) 090200048

(51) Int. Cl. H05K 5/00

(52) U.S. Cl. 361/680

(57) ABSTRACT

A portable computer includes a main board casing that confines a receiving space therein, and that has a rear end coupled pivotally to a display casing, and a top side formed with a keyboard receiving recess. A main board module is received in the receiving space. A keyboard device is disposed removably in the keyboard receiving recess, and includes abase member, a keyboard circuit disposed on a top side of the base member, and a plurality of keys disposed on top of the keyboard circuit and operably associated with the keyboard circuit so as to enable the keyboard circuit to generate a corresponding keyboard signal upon operation of one of the keys. The signal transmission unit, which is coupled to the keyboard circuit and the main board module, makes electrical connection between the keyboard circuit and the main board module when the keyboard device is disposed in the keyboard receiving recess, and breaks electrical connection between the keyboard circuit and the main board module and permits connection between the keyboard circuit and an external electronic device when the keyboard device is removed from the keyboard receiving recess.

### BACKGROUND OF THE INVENTION

1. Field of the Invention

The invention relates to a portable computer, more particularly to a portable computer with a detachable keyboard device.

2. Description of the Related Art

Referring to FIG. 1, a conventional portable computer 100, such as a notebook computer, is shown to comprise a display casing 11, a liquid crystal display (LCD) panel 111 mounted on the display casing 11, a main board casing 13, and a keyboard module 15 mounted securely on the main board casing 13 and connected electrically to circuitry inside the main board casing 13 via a ribbon cable (not shown). The display casing 11 is coupled pivotally to the main board casing 13 and is movable relative to the main board casing 13 between open and closed positions.

In the conventional portable computer 100, the keyboard module 15 is not designed for connection with other electronic devices, such as a desktop computer. For people accustomed to typing on the keyboard module of a portable computer, it would be desirable to provide a portable computer having a keyboard device that can be detached from a main board casing and that can be connected to an external electronic device so as to serve as a user input device for the latter.

### SUMMARY OF THE INVENTION

Therefore, the main object of the present invention is to provide a portable computer having a detachable keyboard device that can be connected to an external electronic device to serve as a user input device for the latter.

According to this invention, a portable computer comprises a display casing, a main board casing, a main board module, a keyboard device, and a signal transmission unit. The main board casing confines a receiving space therein, and has a rear end coupled pivotally to the display casing, and a top side formed with a keyboard receiving recess. The main board module is received in the receiving space. The keyboard device is disposed removably in the keyboard receiving recess, and includes a base member having a top side and an opposite bottom side, a keyboard circuit disposed on the top side of the base member, and a plurality of keys disposed on top of the keyboard circuit and operably associated with the keyboard circuit so as to enable the keyboard circuit to generate a corresponding keyboard signal upon operation of one of the keys. The signal transmission unit, which is coupled to the keyboard circuit and the main board module, makes electrical connection between the keyboard circuit and the main board module to permit transmission of the keyboard signal from the keyboard circuit to the main board module when the keyboard device is disposed in the keyboard receiving recess, and breaks electrical connection between the keyboard circuit and the main board module and is adapted to permit connection between the keyboard circuit and an external electronic device when the keyboard device is removed from the keyboard receiving recess.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional portable computer;

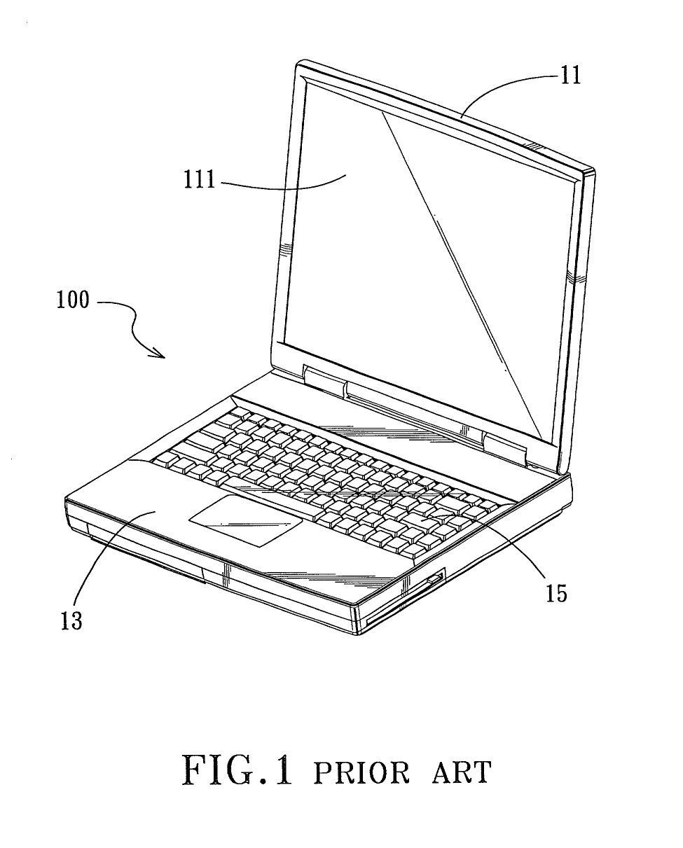

FIG. 2 is a perspective view of the first preferred embodiment of a portable computer with a detachable keyboard device according to the present invention;

FIG. 3 is an exploded perspective view of the keyboard device of the first preferred embodiment;

FIG. 4 is an assembled perspective view of the first preferred embodiment;

FIG. 5 illustrates how connection between the keyboard device of the first preferred embodiment and an external electronic device is established; and

FIG. 6 is a perspective view of the second preferred embodiment of a portable computer with a detachable keyboard device according to the present invention.

### DETAILED DESCRIPTION OF THE PREFERRED EMBODIMENTS

Before the present invention is described in greater detail, it should be noted that like elements are denoted by the same reference numerals throughout the disclosure.

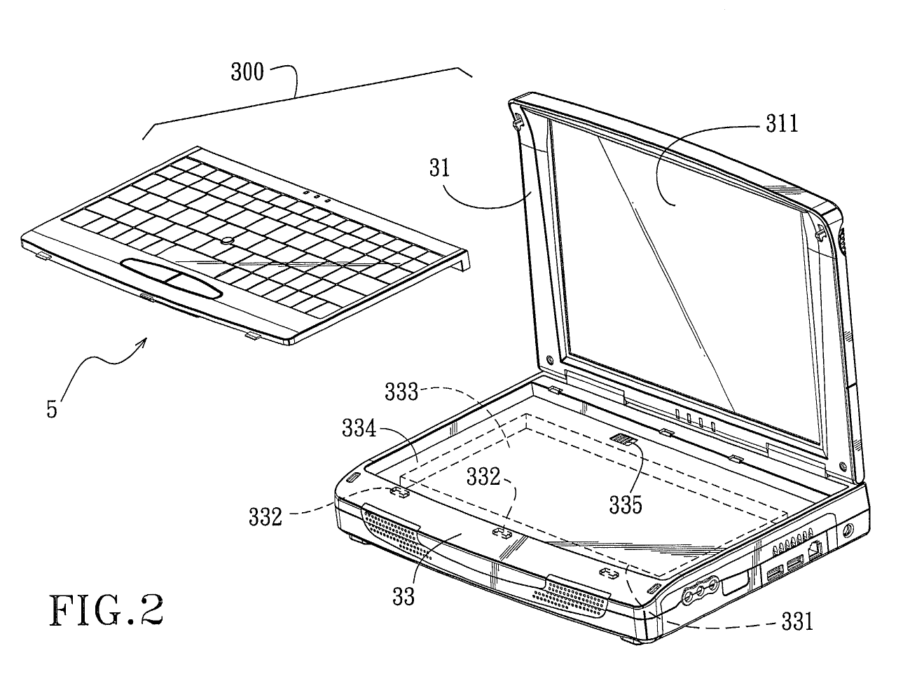

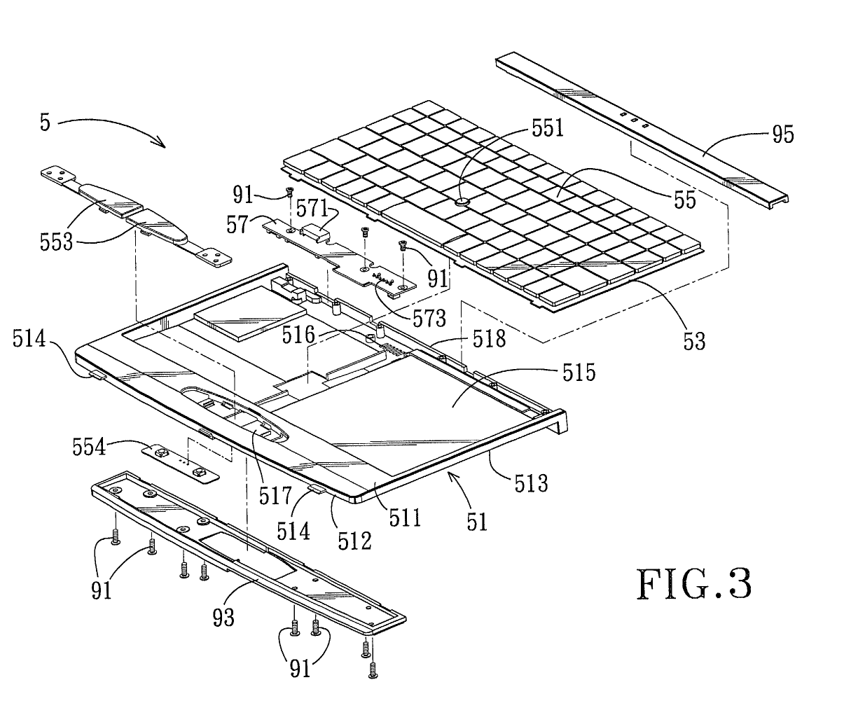

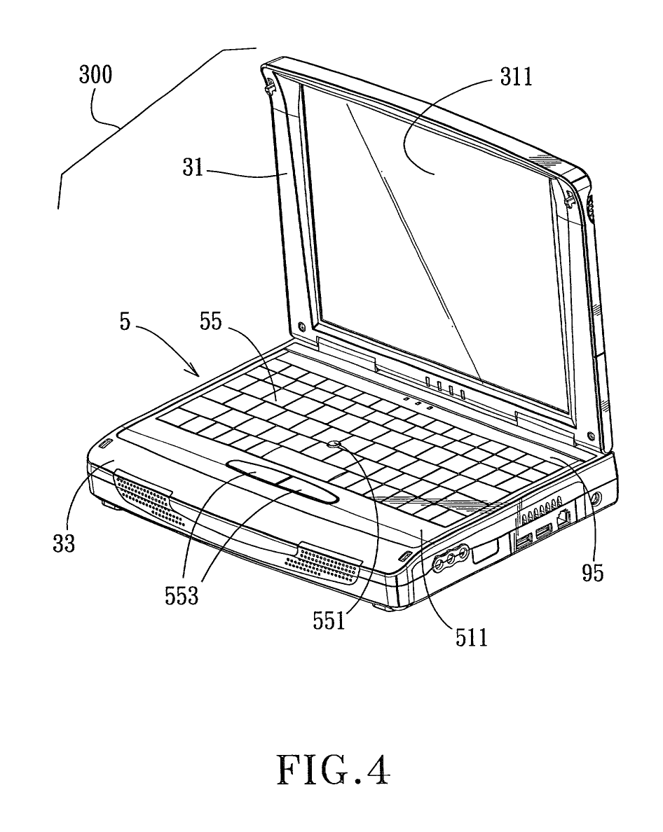

Referring to FIGS. 2, 3 and 4, the first preferred embodiment of a portable computer 300 according to the present invention is shown to be embodied in a notebook computer that comprises a display casing 31, a liquid crystal display module 311 mounted on the display casing 311, a main board casing 33 having a rear end coupled pivotally to the display casing 31, and a main board module 331 disposed in a receiving space 333 that is confined by the main board casing 33. The main board casing 33 has a top side formed with a keyboard receiving recess 334. The recess 334 is confined by a surrounding wall having a wall portion distal to the rear end of the main board casing 33 and formed with a plurality of latch grooves 332. The recess 334 is further confined by a bottom wall that is provided with a set of first terminals 335, which are connected electrically to the main board module 331. The portable computer 300 further comprises a keyboard device 5 that is disposed removably in the keyboard receiving recess 334.

The keyboard device 5 includes a base member 51, a keyboard circuit 53, and a plurality of keys 55. In this embodiment, the base member 51 is a rectangular member having a size and shape that complement those of the keyboard receiving recess 334. The base member 51 has a top side 511 and an opposite bottom side 513. The top side 511 of the base member 51 is formed with a generally rectangular first mounting recess 515 and a generally elliptical second mounting recess 517 that is separate from and that is smaller than the first mounting recess 515. The base member 51 further has a front end 512 formed with a plurality of tongue fasteners 514, and a rear end 518. The tongue fasteners 514 are inserted into the latch grooves 332 in the main board casing 33 for retaining removably the base member 51 in the keyboard receiving recess 334.

The keyboard circuit 53 is received in the first mounting recess 515 and is retained on the base member 51 through the use of latch means or screw fastener means. The keys 55 are disposed on top of the keyboard circuit 53 and are operably associated with the keyboard circuit 53 in a known manner. When one of the keys 55 is pressed toward the keyboard circuit 53, the keyboard circuit 53 will be enabled to generate a corresponding keyboard signal, as is known in the art. Preferably, a cursor control button 551 is disposed among the keys 55 on top of the keyboard circuit 53.

In the present embodiment, a connector unit 57 is retained in the first mounting recess 515 beneath the keyboard circuit 53 through the use of screw fasteners 91, and is connected electrically to the keyboard circuit 53. The connector unit 57 includes an electrical connector 571 that extends beyond the rear end 518 of the base member 51, and a set of second terminals 573 that are received in holes 516 in the base member 51 to enable the second terminals 573 to project from the bottom side 513 of the base member 51. The second terminals 573 press against the first terminals 335 on the bottom wall of the recess 334 when the keyboard device 5 is disposed in the latter, thereby establishing electrical connection between the keyboard circuit 53 and the main board module 331. Thus, the connector unit 57 and the first terminals 335 cooperate to form a signal transmission unit such that the keyboard signals generated by the keyboard circuit 53 can be received by the main board module 331.

In the present embodiment, the connector unit 57 is formed separately from the keyboard circuit 53. However, in a modified embodiment of the keyboard device 5, the connector unit 57 can be integrated with the keyboard circuit 53.

A pair of cursor command keys 553 are mounted in the second mounting recess 517. Each of the cursor command keys 553 is operably associated with a respective one of a pair of micro-switches 554 that are disposed on a base plate 93 and that are connected electrically to the keyboard circuit 53. The base plate 93 is secured to the bottom side 513 of the base member 51 via screws 91. When one of the cursor command keys 553 is operated, the corresponding micro-switch 554 is activated to generate an electrical signal that is transmitted to the keyboard circuit 53. As such, when the keyboard circuit 53 receives the electrical signal from either of the micro-switches 554, or when the keyboard circuit 53 detects operation of the cursor control button 551, a corresponding cursor control signal is generated by the keyboard circuit 53 and is transmitted to the electrical connector 571 and to the second terminals 573 of the connector unit 57.

Preferably, an elongate cover plate 95 is mounted on the top side 511 of the base member 51 adjacent to a rear edge of the same.

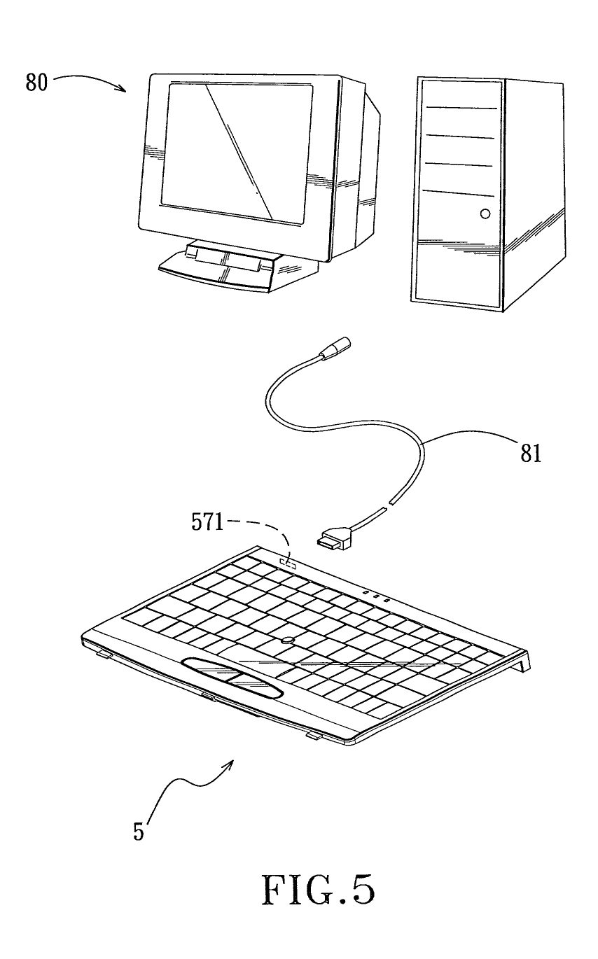

With further reference to FIG. 5, when the keyboard device 5 is detached from the main board casing 33, electrical connection between the keyboard device 5 and the main board module 331 is broken, and an electrical cable 81 can be used to connect the electrical connector 571 of the keyboard device 5 to an input/output port, such as a PS/2 port (not shown), of an external electronic device 80, such as a desktop computer. Thus, keyboard signals generated by the keyboard circuit 53 can be transmitted to the electronic device 80 via the connector unit 57 and the electrical cable 81, thereby enabling the keyboard device 5 to serve as a user input device for the electronic device 80.

In the preferred embodiment, a wired connection is established between the keyboard device 5 and the electronic device 80 for signal transmission therebetween. In another embodiment, the connector unit can be modified to enable wireless signal transmission between the keyboard device and the electronic device.

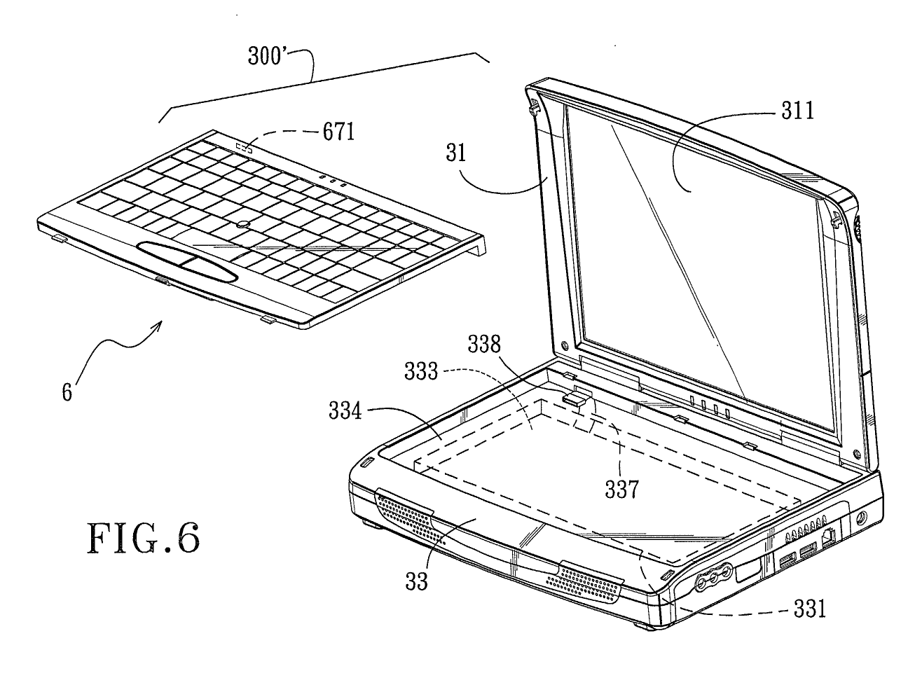

FIG. 6 illustrates the second preferred embodiment of a portable computer 300′ according to the present invention. Unlike the previous embodiment, the keyboard device 6 and the main board casing 33 are not provided with first and second terminals, and the keyboard signals generated by the keyboard circuit (not shown) are provided solely to the electrical connector 671. A ribbon cable 337 has one end connected electrically to the main board module 331 in the receiving space 333, and an opposite end that extends into the keyboard receiving recess 334 and that is provided with a mating connector 338. When the keyboard device 6 is to be disposed in the keyboard receiving recess 334, the mating connector 338 is coupled to the electrical connector 671 to establish electrical connection between the keyboard device 6 and the main board module 331. When the keyboard device 6 is detached from the main board casing 33, it can be connected to an external electronic device (not shown) in a manner similar to that of the previous embodiment.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A portable computer, comprising:
a display casing;
a main board casing confining a receiving space therein, and having a rear end coupled pivotally to said display casing, and a top side formed with a keyboard receiving recess;
a main board module received in said receiving space;
a keyboard device disposed removably in said keyboard receiving recess and including
a base member having a top side and an opposite bottom side,
a keyboard circuit disposed on said top side of said base member, and
a plurality of keys disposed on top of said keyboard circuit and operably associated with said keyboard circuit so as to enable said keyboard circuit to generate a corresponding keyboard signal upon operation of one of said keys; and
a signal transmission unit coupled to said keyboard circuit and said main board module, said signal transmission unit making electrical connection between said keyboard circuit and said main board module to permit transmission of the keyboard signal from said keyboard circuit to said main board module when said keyboard device is disposed in said keyboard receiving recess, said signal transmission unit breaking electrical connection between said keyboard circuit and said main board module and being adapted to permit connection between said keyboard circuit and an external electronic device when said keyboard device is removed from said keyboard receiving recess.

2. The portable computer of claim 1, wherein said signal transmission unit includes:
a set of first terminals disposed in said keyboard receiving recess and connected electrically to said main board module; and
a set of second terminals mounted on said base member and connected electrically to said keyboard circuit, said second terminals pressing against said first terminals to make electrical connection between said keyboard circuit and said main board module when said keyboard device is disposed in said keyboard receiving recess.

3. The portable computer of claim 2, wherein said base member is formed with a set of holes that receive said second terminals and that enable said second terminals to project from said bottom side of said base member.

4. The portable computer of claim 1, wherein said keyboard receiving recess is confined by a surrounding wall that is formed with a plurality of latch grooves, and said base member is formed with a plurality of tongue fasteners that are inserted into said latch grooves for retaining removably said keyboard device in said keyboard receiving recess.

5. The portable computer of claim 1, wherein said keyboard device further includes a cursor control button disposed among said keys on top of said keyboard circuit and operable so as to enable said keyboard circuit to generate a cursor control signal that is received by said signal transmission unit.

6. The portable computer of claim 1, wherein said signal transmission unit includes an electrical connector mounted on said base member and connected electrically to said keyboard circuit, said electrical connector being adapted to connect with an electrical cable so as to permit electrical connection with the external electronic device when said keyboard device is removed from said keyboard receiving recess.

7. The portable computer of claim 1, wherein said signal transmission unit includes:
a ribbon cable having a first end connected electrically to said main board module in said receiving space, and a second end extending into said keyboard receiving recess and provided with a mating connector; and
an electrical connector mounted on said base member and connected electrically to said keyboard circuit, said electrical connector mating with said mating connector to make electrical connection between said keyboard circuit and said main board module when said keyboard device is disposed in said keyboard receiving recess, said electrical connector being adapted to connect with an electrical cable so as to permit electrical connection with the external electronic device when said keyboard device is removed from said keyboard receiving recess.
